(19) United States
(12) Patent Application Publication
(10) Pub. No.: US 2019/0126550 A1
(43) Pub. Date: May 2, 2019

(54) CONNECTION DETERMINATION IN PRINTING APPARATUS

(71) Applicants: Francesc SALAS ROURA, Sant Cugat del Valles (ES); Gonzalo GASTON LLADO, Sant Cugat del Valles (ES); Xavier VILAJOSANA, Sant Cugat del Valles (ES); HEWLETT-PACKARD DEVELOPMENT COMPANY, L.P., Houston, TX (US)

(72) Inventors: Francesc Salas Roura, Sant Cugat del Valles (ES); Gonzalo Gaston Llado, Sant Cugat del Valles (ES); Xavier Vilajosana, Sant Cugat del Valles (ES)

(73) Assignee: HEWLETT-PACKARD DEVELOPMENT COMPANY, L.P., Houston, TX (US)

(21) Appl. No.: 16/095,634

(22) PCT Filed: Jun. 24, 2016
(86) PCT No.: PCT/EP2016/064760

§ 371 Date: Oct. 22, 2018

(51) Int. Cl. B29C 64/295; B29C 64/165; B29C 64/393; G01R 31/04

(52) U.S. Cl. CPC B29C 64/295; B29C 64/165; B33Y 10/00; G01R 31/04; B29C 64/393

(57) ABSTRACT

A method comprises switching on a first radiation source of a plurality of radiation sources. The plurality of radiation sources are for delivering radiation towards a print area of a printing apparatus. Each of the plurality of radiation sources may be connected to control circuitry via one of a plurality of circuit terminals. The method may further comprise detecting, using a detector, a change resulting from radiation from the first radiation source. The method may further comprise determining, using a processor, based on the detected change, connection information indicative of the circuit terminal to which the first radiation source is connected.

### BACKGROUND

Additive manufacturing techniques may generate a three-dimensional object on a layer-by-layer basis through the solidification of a build material. In examples of such techniques, build material is supplied in a layer-wise manner and a solidification method may include heating the layers of build material to cause melting in selected regions. In other techniques, other solidification methods, such as chemical solidification methods or binding materials, may be used. In some examples, the temperature of the build material is increased prior to the melting process.

### BRIEF DESCRIPTION OF DRAWINGS

Examples will now be described, by way of non-limiting example, with reference to the accompanying drawings, in which:

FIG. 1 is a simplified schematic of an example of a heating module for an additive manufacturing apparatus;

FIG. 2 is a flowchart of an example method for determining connection information in an additive manufacturing system;

FIG. 3 is a flowchart of a further example method for determining connection information in an additive manufacturing system;

FIG. 4 is an example of templates for use in a method for determining connection information in an additive manufacturing system;

FIG. 5 is a simplified schematic of an example of apparatus to determine connection information in an additive manufacturing system; and

FIG. 6 is a simplified schematic of an example machine-readable medium with a processor to perform a method of determining connection information in an additive manufacturing system.

### DETAILED DESCRIPTION

Printing apparatus may be used to generate two-dimensional printed images. Additive manufacturing techniques may generate a three-dimensional object through the solidification of a build material. In some examples, the build material may be a powder-like granular material, which may for example be a plastic, ceramic or metal powder. The properties of generated objects may depend on the type of build material and the type of solidification mechanism used. Build material may be deposited, for example on a print bed and processed layer by layer, for example within a fabrication chamber.

In some examples, selective solidification is achieved through directional application of energy, for example using a laser or electron beam which results in solidification of build material where the directional energy is applied. In other examples, at least one print agent may be selectively applied to the build material, and may be liquid when applied. For example, a fusing agent (also termed a ‘coalescence agent’ or ‘coalescing agent’) may be selectively distributed onto portions of a layer of build material in a pattern derived from data representing a slice of a three-dimensional object to be generated (which may for example be generated from structural design data). The fusing agent may have a composition which absorbs energy such that, when energy (for example, heat) is applied to the layer, the build material coalesces and solidifies to form a slice of the three-dimensional object in accordance with the pattern. In other examples, coalescence may be achieved in some other manner.

In addition to a fusing agent, in some examples, a print agent may comprise a coalescence modifying agent (referred to as modifying or detailing agents herein after), which acts to modify the effects of fusing for example by reducing or increasing coalescence or to assist in producing a particular finish or appearance to an object, and such agents may therefore be termed detailing agents. Such a detailing agent may be used to prevent fusing of a portion of build material by cooling the build material, for example.

Additive manufacturing systems may generate objects based on structural design data. This may involve a designer generating a three-dimensional model of an object to be generated, for example using a computer aided design (CAD) application. The model may define the solid portions of the object. To generate a three-dimensional object from the model using an additive manufacturing system, the model data can be processed to generate slices of parallel planes of the model. Each slice may define a portion of a respective layer of build material that is to be solidified or caused to coalesce by the additive manufacturing system.

An example additive manufacturing process may involve various processes. A layer of build material may be formed on a print bed, or build platform using, for example, a build material distributor, which may, in one example, deposit and spread build material onto the print bed at an intended thickness. Prior to the build material being fused, the layer of build material and/or the print bed may be preheated using, for example, a radiation source such as an infrared lamp, or by some other means.

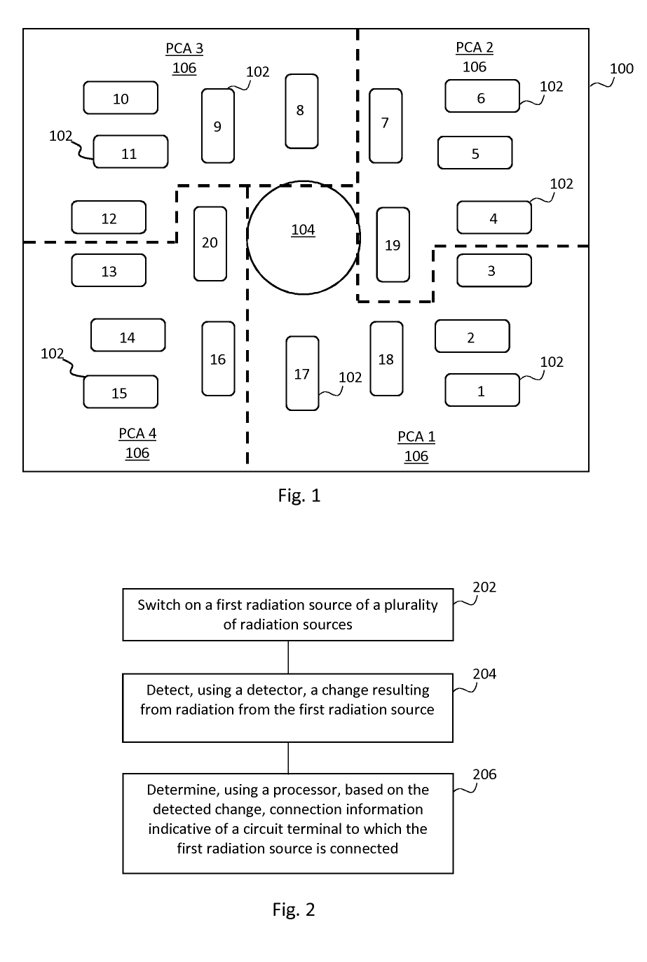

A simplified schematic of an example heating module, which may be a preheating lamp, a fusing lamp, or, more generally, a lamp assembly having an array of lamps, for use in a printing apparatus is shown in FIG. 1. The printing apparatus may, in some examples, be a two-dimensional printing apparatus which may use an array of lamps, such as curing lamps, to dry media onto which ink is printed. In other examples, the printing apparatus may be an additive manufacturing apparatus, used for generating three-dimensional objects. In the following examples, an additive manufacturing apparatus is described; however, the methods described herein may be performed in relation to a two-dimensional printing apparatus.

The heating module 100, in some examples may be located above a print bed, in or above a fabrication chamber of an additive manufacturing apparatus, and may be used to supply radiation, such as heat, into the fabrication chamber and towards the print bed, for example as part of the preheating process discussed above. In such a preheating process, the print bed and/or build material on the print may be heated, for example using the heating module 100, in a uniform manner, to a temperature just below the fusing or melting temperature of the build material to which fusing agent has been applied. In some other examples, the heating module 100 may comprise a lamp used to deliver heat to fuse the build material to which fusing agent has been applied. In a two-dimensional printing apparatus, the heating module 100 may comprise an array of curing lamps, as described above. The heating module 100 may include a plurality of individual lamps, or heat elements 102. In the example shown in FIG. 1, the heating module 100 includes twenty individual heat elements 102, arbitrarily numbered 1 to 20. The terms ‘heat element’, ‘heat lamp’, ‘heat source’ and ‘radiation source’ are used herein interchangeably, and include any such component for generating radiation in a controlled manner, which is capable of causing a detectable change on or to at least a portion of the print bed. As is discussed below, the detectable change may, in some examples, be a temperature change and may, in other examples, be some other change, such as a change in light intensity, colour or reflectivity.

In some examples, the heat elements 102 may be halogen lamps which may generate a large amount of near-infrared radiation. In other examples, infrared light emitting diodes (LEDs) or infrared bar radiators may be used as heat elements 102.

The heat elements 102 are, in the example shown, arranged in a spaced-apart manner on a surface of the heating module 100, in a configuration that allows heat from the heat elements to be distributed approximately evenly or uniformly through the fabrication chamber and onto the print bed, or print area. In other examples, the heating module 100 may include more or fewer heat elements 102, and may be arranged in a different configuration. For example, in an additive manufacturing apparatus having a larger fabrication chamber, the heating module 100 may include more heat elements 102 in order to provide sufficient heat to increase the temperature of the print bed and/or build material on the print bed.

In the example of FIG. 1, a sensor or detector 104 is located approximately centrally on the surface of the heating module 100, and aimed downwards towards the print bed or print area. The detector 104, in some examples, may be a thermopile infrared (IR) sensor, capable of detecting absolute temperatures or temperature changes of a target, such as the print bed. In other examples, the detector may detect some other quantity, such as light intensity, colour or an amount of light reflected from a surface. In the example where the detected change is a change in temperature, the detector 104 may include, or may be connected to, an imaging device, such as a charge-coupled device (CCD), capable of generating and/or recording a visual image representative of the detected temperature or temperature change for at least a portion of the print bed and/or build material on the print bed. In other examples, the heating module 100 may include multiple detectors 104 for measuring temperatures or detecting temperature changes of a target, which may be located among the heat elements 102 or elsewhere within, or remote from, the heating module. The detector may, in some examples, register a temperature increase for those portions of the print bed at which the temperature increases by a defined threshold amount, or at which the temperature increases to above a defined threshold value.

Each of the heat elements 102 is connected to control circuitry (not shown) via which each heat element may be controlled and receive power. In the example of FIG. 1, the heat elements 102 are connected to control circuitry via four printed circuit assemblies (PCAs) 106, numbered arbitrarily PCA 1 to PCA 4. The divisions between the PCAs 106 are shown using dashed lines. In the example shown, the heat elements 102 numbered 1, 2, 3, 17 and 18 are connected to control circuitry via PCA 1, the heat elements numbered 4, 5, 6, 7 and 19 are connected to control circuitry via PCA 2, the heat elements numbered 8, 9, 10, 11 and 12 are connected to control circuitry via PCA 3, and the heat elements numbered 13, 14, 15, 16 and 20 are connected to control circuitry via PCA 4. Thus, in this example, each PCA 106 is connected to five heat elements 102. In other examples, more or fewer PCAs 106 may be used and, in some examples, the heat elements may be connected via a single PCA, or may be connected to control circuitry directly, such that no PCAs are required. In some examples, heat elements 102 are connected to control circuitry via PCAs 106 to reduce the risk of current peaks occurring in the heat elements. The use of PCAs may also assist with the control of power-line flicker and/or the control of the power delivered to each heat element. The use of a PCA may also assist with the detection of short-circuits within the PCA itself or within a connector cable.

In order to create a uniform distribution of heat throughout the fabrication chamber and across the print bed, or over the print area of a two-dimensional printing apparatus, the heat elements 102 may be independently operated, such that each heat element can be controlled to deliver specific amounts of radiation towards a particular area or particular areas of the print bed. The power supplied to each heat element may also be controlled independently. Therefore, each heat element 102 may be connected to a connection terminal of control circuitry (whether or not via a PCA 106) via a corresponding connector (not shown), such as a connection cable or harness. If any of the heat elements 102 are connected incorrectly to the control circuitry, for example if the connections between the control circuity and two of the heat elements 102 are switched, then the heat elements may be caused to operate in an unintended manner. For example, the print area, or print bed, may be caused to heat up in one area when the intention is to heat the print bed up in another area. In another example, some areas of the print bed could be caused to receive heat from more than one heat element, resulting in excessive heating, and/or some areas of the print bed could be caused to receive heat from none of the heat elements, which could result in the print bed or build material not being heated sufficiently uniformly.

A method will now be described which can be performed by a suitable apparatus or system, and which can be used to determine connection information of the heat elements 102 such as, for example, whether a heat element is connected to an incorrect terminal of the control circuitry. FIG. 2 shows a flowchart which describes a method which comprises, at block 202, switching on a first radiation source of a plurality of radiation sources. Switching on a radiation source may comprise supplying power, via a particular circuit terminal of the control circuitry, to the radiation source. The radiation sources may be the heat elements 102 of FIG. 1 and, as discussed above, the plurality of radiation sources may comprise a heat lamp for increasing a temperature within the fabrication chamber, or of a print area in a printing apparatus. The plurality of radiation sources may be for delivering radiation towards a print area in a printing apparatus, and each of the plurality of radiation sources may be connected to control circuitry via one of a plurality of circuit terminals. In order to switch on or control a radiation source, power may be supplied to the radiation source via the control circuitry, for example. As a consequence, heat may be caused to radiate from the radiation source towards a print area in a printing apparatus. In some examples, the radiation source is switched on and left for a period, for example 60 seconds, sufficient for a portion of the print bed to undergo a detectable or measurable temperature change. In some examples, the radiation source 102 may be switched on and left on until the detected temperature increase exceeds a defined threshold, or until some other detectable change has taken effect.

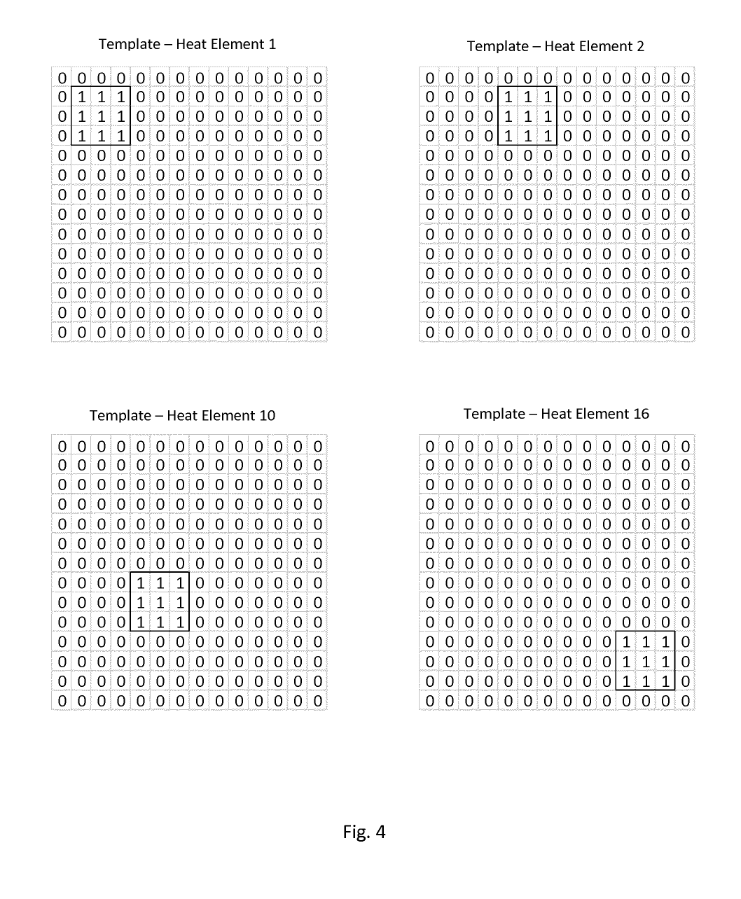

At block 204, the method comprises detecting, using a detector, a change resulting from radiation from the first radiation source. The detector may be the detector 104 discussed above with reference to FIG. 1. In some examples, the detected change may comprise a measurable change of or at a portion of a surface onto which radiation from the first radiation source is directed. The change may, in some examples, comprise a change in temperature caused by the radiation from the first radiation source. The surface may, for example, comprise the print bed of the additive manufacturing apparatus, or a surface of the print area in a two-dimensional printing apparatus. The method further comprises, at block 206, determining, using a processor, based on the detected change, connection information indicative of the circuit terminal to which the first radiation source is connected. In order to make such a determination, a processor analyses the data received by the detector 104 to determine an area or zone on the print bed that undergoes a change, such as a temperature change, as a result of radiation from the first radiation source. The processor may generate a thermal image, or heat map, showing the location and extent of the temperature change caused by the radiation source. In some examples, the processor may then compare the heat map with one or more templates of expected temperature change outcomes that would be caused by heat from each of the plurality of radiation sources 102. From the comparison, the processor may determine which of the radiation sources caused the measured temperature increase on the print bed and, therefore, may determine the circuit terminal to which the first radiation source is connected. Thus, the determining may, in some examples, comprise comparing a location of the portion of the surface with a plurality of templates, each template representing a temperature change caused by radiation from a respective one of the plurality of radiation sources. The determination performed with reference to block 206 is discussed in greater detail below with reference to FIG. 4.

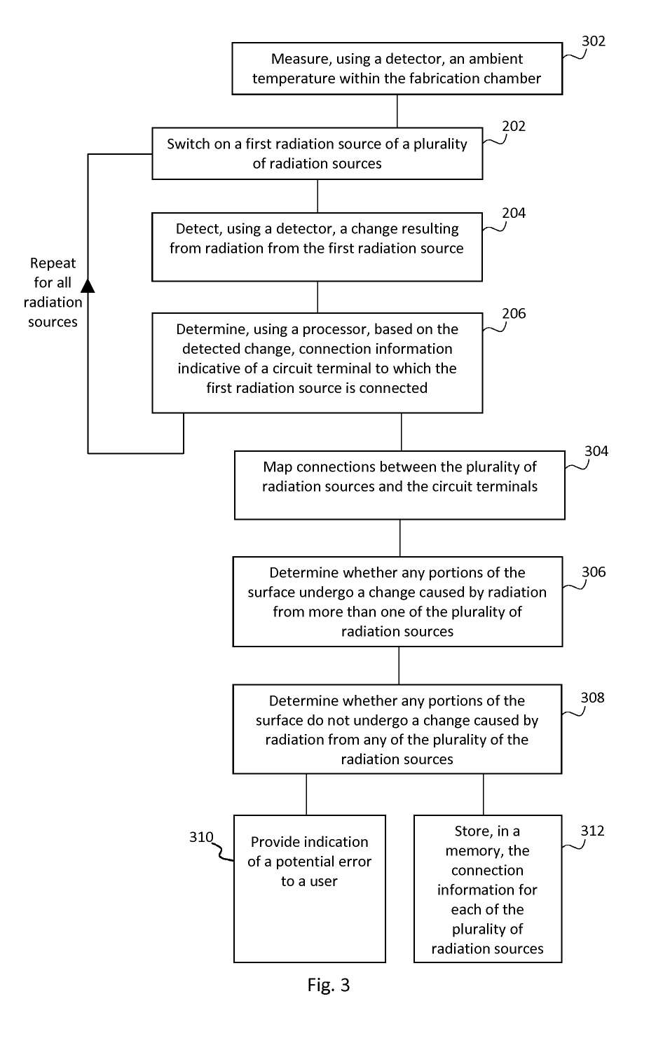

Reference is now made to FIG. 3, which is a flowchart of a further example method for determining connection information in an additive manufacturing system. The method includes blocks 202, 204 and 206 as discussed above with reference to FIG. 2. In addition, the flowchart of FIG. 3 includes additional blocks as discussed below.

According to some examples, the switching on (block 202), the detecting (block 204) and the determining (block 206) processes may be further performed sequentially for each of the other radiation sources of the plurality of radiation sources, as indicated by the arrow extending from block 206 to block 202. In other words, the processes described above with reference to blocks 202, 204 and 206 may be performed for a first radiation source, or heat element 102, then for a second radiation source, and so on, until the processes have been performed for all of the radiation sources in the plurality of radiation sources. In some examples, the method may at this stage store, in a memory, the connection information for each of the plurality of radiation sources.

Prior to switching on the first radiation source, the method may further comprise, in block 302, measuring an ambient temperature within the fabrication chamber, or of the print area. The ambient temperature measurement may be made using the detector 104 of the heating module 100, or by a different thermal sensor located within the fabrication chamber, or near to the print area, and which may form part of the heating module. The measured ambient temperature may be stored in a memory within or remote from the additive manufacturing apparatus, and/or may be measured periodically by one or more sensors located within the fabrication chamber.

After performing the processes described above with reference to FIG. 2 for each of the plurality of radiation sources in the heating module, the method may comprise, in block 304, mapping the connections between the plurality of radiation sources and the circuit terminals. That is to say, a processor or computing apparatus may, using the detected temperature increases for all of the radiation sources 102, match, or pair, the circuit terminal via which a radiation source was supplied switched on, or activated, with the particular radiation source determined to have caused the detected temperature increase. Thus, the system may map the connection between each radiation source and its respective circuit terminal. The mapping information may be stored in the memory and used by the system during subsequent additive manufacturing processes. By using the described method, when such a heating module is being assembled, the individual radiation sources, or heat elements, can be connected to any of the circuit terminals, in any order. Once all of the heat elements have been connected, the method described herein may enable the connection information to be determined and stored. The system may then use the information, during an additive manufacturing process, to activate the heat elements of the heating module in order, as intended for the preheating process. In the event, for example, that a service engineer is to replace multiple radiation sources or a cables in the heating module, the engineer can reconnect the radiation sources to any of the circuit terminals. By employing the described method, the radiation sources can be mapped and the mapping information can be stored and used in any subsequent additive manufacturing processes.

Once the system has determined which area or zone of the print area, or print bed, is affected (changed, for example by being heated up) by each radiation source 102, it may be possible to determine whether any connection errors exist in the system, or whether there exist any other errors concerning the radiation sources. In some examples, the method may further comprise, in block 306, determining, using a processor, whether any portions of the surface undergo a change caused by radiation from more than one of the plurality of the radiation sources. Thus, it is possible to determine whether any portions of the print bed are receiving radiation from two or more radiation sources 102, rather than from a single radiation source. This may result from a radiation source 102 being tilted or aimed incorrectly, such that radiation from the source is unintentionally directed to a portion of the print bed served by another radiation source.

The method may, in some examples, comprise, in block 308, determining, using a processor, whether any portions of the surface do not undergo a change caused by radiation from any of the plurality of the radiation sources. Thus, it is possible to determine whether any portions of the print bed are receiving no radiation (or an amount of radiation falling below a defined threshold) from any of the radiation sources 102. Again, this might be indicative of a radiation source 102 being tilted or aimed incorrectly, or of a faulty connection between the radiation source and the control circuitry.

In some examples, the method may include making the determinations of both blocks 306 and 308, while in other examples, one of these determinations, or neither of the determinations, may be made. If either of the determinations of blocks 306 or 308 are made, and a potential error (for example, an area is receiving heat from two sources or an area is not receiving heat from any sources) is identified, then the method according to some examples may further comprise, at block 310, providing an indication of a potential error to a user. Such an indication may comprise an audio warning, such as an alarm signal, or visual warning, such as a warning message displayed on a display of the additive manufacturing apparatus, for example. An indication may be made to the user when it is determined that either (i) a portion of the print bed undergoes a change caused by radiation from more than one of the plurality of the radiation sources; or (ii) a portion of the surface does not undergo a change caused by radiation from any of the plurality of the radiation sources.

In some examples, the method may determine that a heat element in the heating module is not generating radiation when it is switched on. For example, the method may detect that no current consumption is measured by the PCA via which a particular heat element is connected. In other examples, the method may determine that a heat element in the heating module has malfunctioned. For example, the method may detect that the current consumption by a particular heat element is lower or higher than expected.

The method, may further comprise, at block 312, storing, in a memory, the connection information for each of the plurality of radiation sources. In some examples, the storing (block 312) may be done after the determinations made in blocks 306 and/or 308, if no potential errors are identified, as shown in FIG. 3. In other examples, however, connection information may be stored in a memory at other points in the method. For example, connection information relating to a radiation source may be stored in a memory after block 206, before switching on the next radiation source in the sequence. Similarly, connection information, such as the connection mapping information may be stored in a memory after block 306. In some examples, connection information may be stored in a memory at various stages of the method, or after each block has been performed. The memory in which the information is stored may, in some examples, be a non-volatile memory, such as, for example, a read-only memory (ROM), an erasable programmable read-only memory (EPROM), or a flash memory.

The processes discussed herein with reference to blocks in FIGS. 2 and 3 may, in some examples, each be performed by a separate processor or processing apparatus. In other examples, the processes may be performed by a single processor or processing apparatus, or may be shared among a plurality of processors.

The determining process discussed above with reference to block 206 will now be discussed in greater detail with reference to FIG. 4 and using the example of the detected change being a change in temperature. The detecting process of block 204 may provide data concerning the particular area or zone of the print bed which is heated up as a result of the particular heat element 102 being switched on, or activated. The area directly beneath the heat element 102 being activated may receive the greatest amount of heat from the activated heat element. Since heat from the activated heat element 102 will spread to other areas of the print bed (i.e. areas not directly beneath the activated heat element), the particular area or zone of the print bed considered to be affected by the activated heat lamp may be an area of the print bed within which the temperature is determined to have increased by a particular defined amount, or an area of the print bed within which the temperature is determined to have increased to above a defined threshold. In this way, temperature changes of areas of the print bed that are not directly under the activated heat lamp may be disregarded.

For each heat element, the method may compare, using a processor, the detected temperature change on the print bed with a plurality of templates, examples of which are shown schematically in FIG. 4. A memory within, or accessible by, the printing apparatus may store a template corresponding to each of the heat elements 102 of the heating module. Thus, for the heating module of FIG. 1, the memory may store twenty templates. Each template represents the surface, for example the print bed, onto which the heat elements may direct heat, and show an area or zone of the surface that is expected to be heated up by the activation of the corresponding heat element. For example, FIG. 4 shows four templates, each representing a surface of 14 by 14 unit areas. The example shown in FIG. 4 represents a system having a heating module with sixteen heat elements, as is apparent from the discussion below. In other examples, the templates may be of a different size, the template size selected, for example, based on the size of the print bed and/or on the number of heat elements in the heating module.

Referring to FIG. 4, the first template, labelled “Template—Heat Element 1” corresponds to a first of the sixteen heat elements, and shows schematically, as a square of nine 1s (ones), an area of the print area or print bed that is expected or intended to be heated up (significantly, or to above a defined threshold) by the first heat element (heat element 1) positioned directly above that area of the print bed. All other areas of the print bed, which are not positioned directly below the first heat element and, therefore, are not expected or intended to be heated up by that heat element, are denoted with 0s (zeroes). The second template shown in FIG. 4, labelled “Template—Heat Element 2” corresponds to a second of the sixteen heat elements (the second heat element in this example being adjacent to the first heat element), and shows, as a square of 1s, an area of the print bed that is expected or intended to be heated up by the second heat element (heat element 2). Similarly, the other areas of the print bed, which are not positioned directly below the second heat element and, therefore, are not expected or intended to be heated up by that heat element, are denoted with 0s (zeroes). The third and fourth templates, labelled “Template—Heat Element 10” and “Template—Heat Element 16”, correspond to a tenth heat element and a sixteenth heat element respectively, again with those areas of the print bed that are heated by the heat elements shown with 1s, and those areas not heated by the heat elements shown with 0s. It will be appreciated that similar templates correspond to the other heat elements.

In other examples, templates may include values other than 1 and 0. For example, a template may include fields (i.e. squares) having values of 0.5, which may represent areas adjacent to the area directly under the heat element, and which, as a consequence, receive a relatively smaller amount of heat or radiation from the heat element.

In the example of FIG. 4, the output of the activated heat element, as detected by the detector 104, is compared to each of the templates. If the detected output is determined to correspond to a particular one of the templates (that is, if the area of the detected temperature increase falls substantially within the area in the template denoted with 1s), then the system may determine that the output was caused by the heat element associated with that particular template. The comparison of the detected output with the templates may, in some examples, involve using a processor to quantify the detected output (for example by applying a numerical value to each unit area of the surface onto which the radiation is directed, the numerical value being representative of the amount of radiation detected within each unit area), and then multiply the quantified output of each unit area with the value (for example 0, 0.5 or 1) of the corresponding unit area of each template. The processor may determine which template produces the largest total value (when the unit areas have been multiplied together and summed), and the processor may then determine that the detected output was caused by the heat element associated with that particular template which produces the largest total value.

While the above method lends itself to use in additive manufacturing apparatus which use a fusing lamp to fuse portions of build material and a preheating lamp to increase the temperature of the print bed and/or the build material prior to fusing, the method is also suitable for use in a laser sintering system, such as a selective laser sintering (SLS) system, in which a heating module may be used to provide heat during a preheating process, but a laser is used to selectively fuse portions of build material.

The above method may also be used in systems where radiation from the radiation sources is used in a fusing process rather than, or in addition to, a preheating process. For example, the method described herein may be used in systems in which ultraviolet (UV)-curable inks or latex inks are used.

The method described herein may be considered to be a calibration of the heat elements of radiation sources of the heating module, which may be performed while, or after, the heating module or printing apparatus is manufactured, during or after a servicing procedure, or as a user calibration between uses, or periodically.

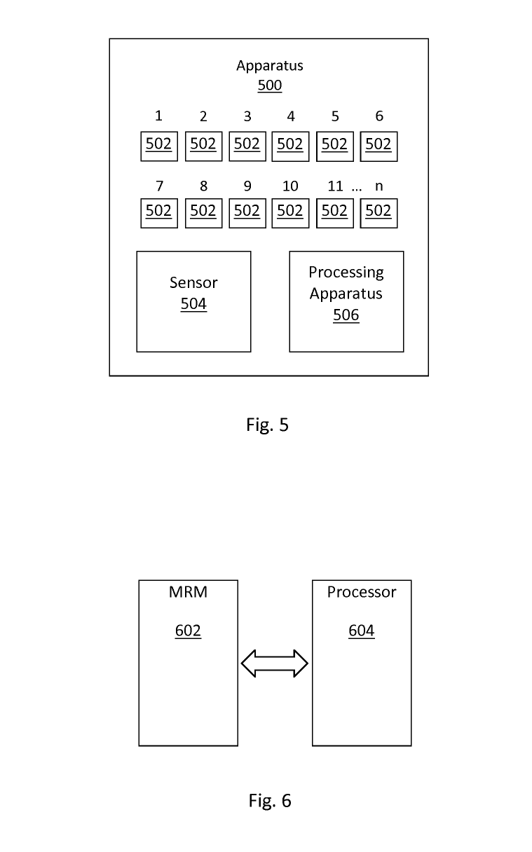

FIG. 5 shows a simplified schematic of an example of apparatus 500 to determine connection information in a printing apparatus, such as an additive manufacturing system. The apparatus 500 comprises a plurality of heat sources 502 to direct heat towards a print area in a printing apparatus. Each of the plurality of heat sources 502 is connected to control circuitry via one of a plurality of circuit terminals. In the example shown in FIG. 5, the apparatus 500 includes n heat sources, numbered 1, 2 . . . 10, 11 . . . n. As discussed above, the number of heat sources used in an apparatus may be selected based at least in part on the size of the print bed and the fabrication chamber to be heated. The apparatus 500 further comprises a sensor 504 to measure a change in temperature resulting from heat from a particular heat source 502 of the plurality of heat sources. The apparatus 500 further comprises processing apparatus 506 to calculate, based on the measured change in temperature, connection information identifying the particular circuit terminal to which the particular heat source is connected.

In some examples, the heat sources 502 may correspond to the heat elements 102 of FIG. 1, and/or the sensor 504 may correspond to the detector 104 of FIG. 1.

The sensor 504 may, in some examples, measure a change in temperature of a portion of a surface onto which heat from the first heat source is directed. In some examples, the surface comprises a print area of a printing apparatus, or a print bed of the additive manufacturing apparatus.

In other examples, the sensor 504 may measure a change other than a change in temperature. For example, the sensor 504 may detect or measure light intensity, colour, or an amount of light reflected from a surface.

FIG. 6 shows a machine-readable medium 602 associated with a processor 604. The machine-readable medium 602 comprises instructions which, when executed by the processor 604, cause the processor to activate, successively, each heat lamp in a plurality of heat lamps, the plurality of heat lamps for directing heat towards a print area in a printing apparatus, wherein each of the plurality of heat lamps is connected to control circuitry via one of a plurality of connectors. The machine-readable medium 602 may further comprise instructions which, when executed by the processor 604, cause the processor to identify, using detection apparatus, a thermal change caused by heat from each heat lamp. The machine-readable medium 602 may further comprise instructions which, when executed by the processor 604, cause the processor to ascertain, based on the identified thermal change for each heat lamp, mapping information identifying the particular connector to which each heat lamp is connected.

In some examples, the identified thermal change comprises an indication of a position of a change in temperature of a portion of a surface onto which heat from the heat lamp is directed. The machine-readable medium 602 may further comprise instructions which, when executed by the processor 604, cause the processor to provide an indication to a user when it is determined that either: (i) a portion of the surface undergoes a temperature change caused by heat from more than one of the plurality of the heat lamps; or (ii) a portion of the surface does not undergo a temperature change caused by heat from any of the plurality of the heat lamps.

As discussed above, the indication to a user may be made, for example, as an audible or visual indication, such as a warning signal or warning message.

In other examples, the detection apparatus may be used by the processor to identify a change other than a thermal change. For example, the detection apparatus may detect or measure light intensity, colour, or an amount of light reflected from a surface.

Examples in the present disclosure can be provided as methods, systems or machine readable instructions, such as any combination of software, hardware, firmware or the like. Such machine readable instructions may be included on a computer readable storage medium (including but is not limited to disc storage, CD-ROM, optical storage, etc.) having computer readable program codes therein or thereon.

The present disclosure is described with reference to flow charts and/or block diagrams of the method, devices and systems according to examples of the present disclosure. Although the flow diagrams described above show a specific order of execution, the order of execution may differ from that which is depicted. Blocks described in relation to one flow chart may be combined with those of another flow chart. It shall be understood that each flow and/or block in the flow charts and/or block diagrams, as well as combinations of the flows and/or diagrams in the flow charts and/or block diagrams can be realized by machine readable instructions.

The machine readable instructions may, for example, be executed by a general purpose computer, a special purpose computer, an embedded processor or processors of other programmable data processing devices to realize the functions described in the description and diagrams. In particular, a processor or processing apparatus may execute the machine readable instructions. Thus functional modules of the apparatus and devices may be implemented by a processor executing machine readable instructions stored in a memory, or a processor operating in accordance with instructions embedded in logic circuitry. The term ‘processor’ is to be interpreted broadly to include a CPU, processing unit, ASIC, logic unit, or programmable gate array etc. The methods and functional modules may all be performed by a single processor or divided amongst several processors.

Such machine readable instructions may also be stored in a computer readable storage that can guide the computer or other programmable data processing devices to operate in a specific mode.

Such machine readable instructions may also be loaded onto a computer or other programmable data processing devices, so that the computer or other programmable data processing devices perform a series of operations to produce computer-implemented processing, thus the instructions executed on the computer or other programmable devices realize functions specified by flow(s) in the flow charts and/or block(s) in the block diagrams.

Further, the teachings herein may be implemented in the form of a computer software product, the computer software product being stored in a storage medium and comprising a plurality of instructions for making a computer device implement the methods recited in the examples of the present disclosure.

While the method, apparatus and related aspects have been described with reference to certain examples, various modifications, changes, omissions, and substitutions can be made without departing from the spirit of the present disclosure. It is intended, therefore, that the method, apparatus and related aspects be limited only by the scope of the following claims and their equivalents. It should be noted that the above-mentioned examples illustrate rather than limit what is described herein, and that those skilled in the art will be able to design many alternative implementations without departing from the scope of the appended claims. Features described in relation to one example may be combined with features of another example.

The word “comprising” does not exclude the presence of elements other than those listed in a claim, “a” or “an” does not exclude a plurality, and a single processor or other unit may fulfil the functions of several units recited in the claims.

The features of any dependent claim may be combined with the features of any of the independent claims or other dependent claims.

1. A method comprising:
switching on a first radiation source of a plurality of radiation sources, the plurality of radiation sources for delivering radiation towards a print area of a printing apparatus, wherein each of the plurality of radiation sources is connected to control circuitry via one of a plurality of circuit terminals;
detecting, using a detector, a change resulting from radiation from the first radiation source;
determining, using a processor, based on the detected change, connection information indicative of the circuit terminal to which the first radiation source is connected.

2. The method of claim 1, wherein the change comprises a change in temperature caused by the radiation from the first radiation source.

3. The method of claim 1, wherein the switching on, the detecting and the determining are further performed sequentially for each of the other radiation sources of the plurality of radiation sources.

4. The method of claim 3, further comprising storing, in a memory, the connection information for each of the plurality of radiation sources.

5. The method of claim 3, further comprising mapping the connections between the plurality of radiation sources and the circuit terminals.

6. The method of claim 1, wherein the detected change comprises a measurable change of or at a portion of a surface onto which radiation from the first radiation source is directed.

7. The method of claim 6, wherein the determining comprises comparing a location of the portion of the surface with a plurality of templates, each template representing a change caused by radiation from a respective one of the plurality of radiation sources.

8. The method of claim 6, further comprising determining, using a processor, whether any portions of the surface undergo a change caused by radiation from more than one of the plurality of the radiation sources.

9. The method of claim 6, further comprising determining whether any portions of the surface do not undergo a change caused by radiation from any of the plurality of the radiation sources.

10. The method of claim 6, further comprising:
providing an indication to a user when it is determined that either:
a) a portion of the surface undergoes a change caused by radiation from more than one of the plurality of the radiation sources; or
b) a portion of the surface does not undergo a change caused by radiation from any of the plurality of the radiation sources.

11. Apparatus comprising:
a plurality of heat sources to direct heat towards a print area of a printing apparatus, wherein each of the plurality of heat sources is connected to control circuitry via one of a plurality of circuit terminals;
a sensor to measure a change in temperature resulting from heat from a particular heat source of the plurality of heat sources; and
processing apparatus to calculate, based on the measured change in temperature, connection information identifying the particular circuit terminal to which the particular heat source is connected.

12. Apparatus according to claim 11, wherein the sensor is to measure a change in temperature of a portion of a surface onto which heat from the first heat source is directed.

13. Apparatus according to claim 12, wherein the surface comprises a print bed of the additive manufacturing apparatus.

14. A machine-readable medium comprising instructions which, when executed by a processor, cause the processor to:
activate, successively, each heat lamp in a plurality of heat lamps, the plurality of heat lamps for directing heat towards a print area of a printing apparatus, wherein each of the plurality of heat lamps is connected to control circuitry via one of a plurality of connectors;
identify, using detection apparatus, a thermal change caused by heat from each heat lamp; and
ascertain, based on the identified thermal change for each heat lamp, mapping information identifying the particular connector to which each heat lamp is connected.

15. A machine-readable medium according to claim 14, wherein the identified thermal change comprises an indication of a position of a change in temperature of a portion of a surface onto which heat from the heat lamp is directed, the machine-readable medium further comprising instructions which, when executed by the processor, cause the processor to:
provide an indication to a user when it is determined that either:
a) a portion of the surface undergoes a temperature change caused by heat from more than one of the plurality of the heat lamps; or
b) a portion of the surface does not undergo a temperature change caused by heat from any of the plurality of the heat lamps.
